(19) United States
(12) Patent Application Publication
(10) Pub. No.: US 2013/0081686 A1
(43) Pub. Date: Apr. 4, 2013

(54) CAVITY MODE ENHANCEMENT IN DYE-SENSITIZED SOLAR CELLS

(71) Applicants: Alex B. F. Martinson, Woodridge, IL (US); Noel C. Giebink, Downers Grove, IL (US); Gary P. Wiederrecht, Elmhurst, IL (US); Daniel Rosenmann, Naperville, IL (US); Michael R. Wasielewski, Glenview, IL (US); Michael J. Pellin, Naperville, IL (US)

(72) Inventors: Alex B. F. Martinson, Woodridge, IL (US); Noel C. Giebink, Downers Grove, IL (US); Gary P. Wiederrecht, Elmhurst, IL (US); Daniel Rosenmann, Naperville, IL (US); Michael R. Wasielewski, Glenview, IL (US); Michael J. Pellin, Naperville, IL (US)

(73) Assignee: The University of Chicago

(21) Appl. No.: 13/250,488

(22) Filed: Sep. 30, 2011

(51) Int. Cl. H01L 51/44; H01L 31/0224; H01L 31/18; H01L 31/0232

(52) U.S. Cl. 136/256; 136/263; 136/259; 438/98; 257/E31.124

(57) ABSTRACT

Systems and methods for cavity mode enhancement in dye-sensitized solar cells are provided. A dye-sensitized solar cell generally comprises a transparent substrate, an anode layer, an oxide layer, a dye layer, a cathode, and an electrolyte. The anode layer is deposited on a surface of the transparent substrate. The oxide layer is deposited on the anode layer and the dye is deposited on the oxide layer. A cathode is disposed adjacent to the dye layer and an electrolyte is disposed between the anode layer and the cathode.

### STATEMENT OF GOVERNMENT INTEREST

The United States Government claims certain rights in this invention pursuant to Contract No. DE-ACO2-06CH11357 between the United States Department of Energy and UChicago Argonne, LLC, representing Argonne National Laboratory.

### FIELD OF THE INVENTION

The present invention relates generally to solar energy generation. More particularly, the present invention relates to systems and methods for improving the efficiency of dye-sensitized solar cells and the use of dye-sensitized solar cells for generating fuel.

### BACKGROUND

This section is intended to provide a background or context to the invention that is recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

Dye-sensitized solar cells (DSSCs) differ from conventional solar cells in that they rely on a large area nanoparticle network to achieve sufficient absorption of sunlight. This approach limits the opportunities to further increase DSSC power efficiency because it necessarily restricts the choice of redox shuttles to those compatible with the long electron transit times and ample recombination opportunities inherent to the nanoparticle-based architecture. In one embodiment, the present invention is directed to a unity roughness photoelectrode design that affords adequate light absorption under resonance conditions while dramatically reducing the parasitic dark current density. As will be further described below, the following demonstrates a resonantly coupled cavity scheme on a planar, thin-film DSSC with a polarized, monochromatic incident photon-to-current efficiency (IPCE) of 17% from a single monolayer of a conventional Ru-dye. Upon illumination on resonance, open-circuit voltages reach 1 V, thereby approaching the theoretical limit for open-circuit voltage set by the dye and redox shuttle energy levels.

DSSCs have been optimized through nearly two decades of worldwide research to reach a local optimum that enables photoconversion of nearly all incident light above the dye optical energy gap. Further increasing the power conversion efficiency of these cells requires either extending the dye absorption toward longer wavelengths to absorb more of the solar spectrum or reducing the loss in potential of photoexcited carriers—that is, increasing the open circuit voltage (V_{oc}). This loss in potential is especially large in DSSCs as compared to crystalline inorganic cells: the most efficient DSSCs 10 have V_{oc}=0.75 to 0.85 V, representing approximately a 50% reduction from their optical bandgap of approximately 1.6 eV, whereas for a GaAs cell with V_{oc}=1.11 V and a bandgap of 1.4 eV, the loss is only approximately 25%.

Nearly all of the excess voltage loss in DSSCs can be traced back to the large roughness of the photoelectrode, which usually consists of an approximately 10 μm thick film of sintered, metal oxide wide-bandgap semiconducting nanoparticles. This porous framework is necessary to obtain the approximate 1000-fold surface area enhancement required to chemically bind enough dye to absorb greater than 90% of the incident above-bandgap sunlight. Although this architecture has led to DSSC power conversion efficiencies (ηⱼ) reaching 11%, it is also the chief obstacle to improving upon the current local optimization in DSSC performance.

In recent analyses of the loss in potential of DSSCs, two factors are found to account for the majority of losses. First, a significant loss can be avoided if the heterogeneity of electron injection could be reduced such that all electrons are injected at the potential at which the average electron is currently injected. This heterogeneity is due in part to energetic disorder among the different dye binding sites that stems from the nanoparticle nature of the semiconductor photoelectrode. The greatest voltage loss, however, is due to the large overpotential for dye regeneration by the I⁻/I₃⁻ redox couple, which amounts to approximately 0.5-0.6 eV. Although not optimal from an energy loss standpoint, this multi-electron, multi-step redox couple is uniquely suited to inhibiting the dark reaction across the very large liquid/solid interface. Several promising alternative redox shuttles capable of regenerating dyes with smaller overpotential have been reported. Unfortunately, to date, a significant increase in the dark current densities result in a voltage loss, as determined by the diode equation, largely offsetting the original reduction in dye regeneration overpotential.

A planar, thin-film photoelectrode provides a simple path to improving performance in both of these respects by potentially narrowing the energetic distribution of dye binding sites and reducing the specific solid/liquid heterojunction area (in which recombination is roughly first order) by several orders of magnitude. The challenge with this strategy is to maintain sufficient optical absorption with the correspondingly lower volume of surface bound dye. To this end, there has been significant effort to design a “super-chromophore” that exhibits the broadband absorption of traditional Ru-based dyes but with greater extinction. Research in this area has resulted in effective dyes with peak extinction coefficients (ε) up to 300,000 M⁻¹ cm⁻¹ but, unfortunately, the increased ε is largely offset by reduced packing density and lower ε in other regions of the visible spectrum such that the required roughness of the photoelectrode is of the same order (1000x) as that required of the Ru-based dye (N719) (ε˜14,000 M⁻¹ cm⁻¹) used in the most efficient DSSC.

An alternative approach involves optical concentration on the nanoscale. This has previously been explored using localized surface plasmon resonances (LSPR) supported by metal nanoparticles, which enhance the electromagnetic field in the vicinity of traditional DSSC chromophores and lead to a 7-fold improvement in the IPCE conversion efficiency relative to that of a comparable photoelectrode. While this approach is promising, a route to planar DSSCs with peak IPCE>1% has remained elusive.

DSSCs are one of the least expensive solar cell technologies, but they are relatively inefficient at converting solar energy into electric energy. While research in recent years has focused on improving efficiency, it has remained at approximately 11%. Improving the efficiency of DSSCs would provide a scalable cost-effective solar energy generation technology.

### SUMMARY

Various embodiments of the present invention relate to systems and methods for improving the efficiency of dye-sensitized solar cells. In general, embodiments of the device include a transparent substrate, a photoelectrode, a dye layer, an electrolyte, and a cathode. In one embodiment, a DSSC is provided. The DSSC generally comprises a transparent substrate, an anode layer, an oxide layer, a dye layer, a cathode, and an electrolyte. The anode layer is deposited on a surface of the transparent substrate. The oxide layer is deposited on the anode layer and the dye is deposited on the oxide layer. A cathode is disposed adjacent to the dye layer and an electrolyte is disposed between the anode layer and the cathode.

These and other features of the invention, together with the organization and manner of operation thereof, will become apparent from the following detailed description when taken in conjunction with the accompanying drawings, wherein like elements have like numerals throughout the several drawings described below.

### BRIEF DESCRIPTION OF THE DRAWINGS

FIG. 1 is a schematic of the device and illumination geometry constructed in accordance with an embodiment of the present invention. The zoom circle in FIG. 1 depicts the relative thickness of the anode layer (40 nm), the metal oxide wide-bandgap semiconducting thin film (80 nm) (“oxide layer”), and the dye layer (1 nm). The field intensity calculated on resonance for λ=543 nm illumination as a function of position within the photoelectrode overlays the illustration. A depiction of the N719 dye is included in which TBA=tetrabutylammonium. The right most inset is a scanning electron microscope image of a ZnO photoelectrode in cross-section, prior to dye loading.

FIG. 2 illustrates predicted (lines) and measured (symbols) photoelectrode reflectivity at λ=543 nm as a function of illumination angle at several stages of device fabrication: Glass/Ag (36°), glass/Ag/ZnO (47°), and glass/Ag/ZnO/dye/electrolyte (74° upper). The transverse magnetic (TM) surface plasmon polariton mode is accessible in the Ag-only film, while the first transverse electric (TE) guided mode is accessible in subsequent stages. The predicted IPCE (74° lower line) peaks at 24% whereas the measured value (lower symbols) peaks at 17%.

FIGS. 3(a)-(b) illustrate current density versus applied potential (J-V) in the dark (solid black line) and under illumination on resonance (solid gray line) for a ZnO-based device. The J-V is characteristic of a flat, ZnO control device built on a TCO under broadband illumination at normal incidence (dashed gray). FIG. 3(a) provides a linear scale of the current density and FIG. 3(b) provides a log scale of the absolute value of current density.

FIG. 4(a)-(b) illustrate current density versus applied potential (J-V) in the dark (solid black line) and under illumination on resonance (solid gray line) for a bilayer-based (ZnO/TiO₂) planar device. The J-V of a nanoparticle TiO₂ DSSC under broadband normally (e.g. perpendicular) incident light (dashed gray line, scaled by 1/10 for clarity in FIG. 4(a)) and in the dark (dashed black line) are plotted for comparison. FIG. 4(a) provides a linear scale of the current density and FIG. 4(b) provides a log scale of the absolute value of current density.

FIG. 5 illustrates relevant processes (the movement of electrons within the DSSC) under illumination in a DSSC with N719 dye (bandgap˜1.6 eV) and iodide-based electrolyte at an applied potential of 1.01 V. Forward processes (solid arrows) are in kinetic competition with recombination pathways (dashed arrows). The primary dark current pathway, electrons in TiO₂ scavenged by I₃⁻, has been omitted for clarity.

FIG. 6 illustrates the light harvesting efficiency (LHE) of an N719 dye on planar photoanodes (solid black line) as compared to IPCE spectra of a control device without Ag (solid gray line) and cavity mode enhanced DSSC (dashed line) at normal incidence. The HeNe wavelength used for resonance measurements (λ=543 nm) is illustrated as a vertical line for reference.

FIG. 7 illustrates current density versus applied voltage in the dark and light for planar (diamond and triangle symbols) and nanoparticle (square and circle symbols) DSSC. Best fits to the diode equation are shown as dashed lines.

### DETAILED DESCRIPTION OF VARIOUS EMBODIMENTS

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. It will be readily understood that the aspects of the present disclosure, as generally described herein, and illustrated in the figures, can be arranged, substituted, combined, and designed in a wide variety of different configurations, all of which are explicitly contemplated and made part of this disclosure.

An embodiment relates to a new route to improve the LHE of planar DSSCs 10 by coupling monochromatic light to guided modes supported by the semiconductor thin-film photoelectrode 12. In coupling to guided modes, dye 22 absorption is maximized through a resonant increase of the electromagnetic field intensity in the plane of the surface-bound dye 22. This approach achieves an IPCE of 17% from a single dye 22 monolayer for ZnO-based cells and V_{oc}=1.0 V for TiO₂/ZnO bilayer cells. The latter result approaches the theoretical limit for V_{oc} set by the energetics of the N719 dye 22 and I⁻/I₃⁻ redox shuttle. By dramatically reducing the interfacial area over which the dark current flows, planar electrodes provide an exciting direction for device design and new opportunities for understanding losses in DSSCs 10.

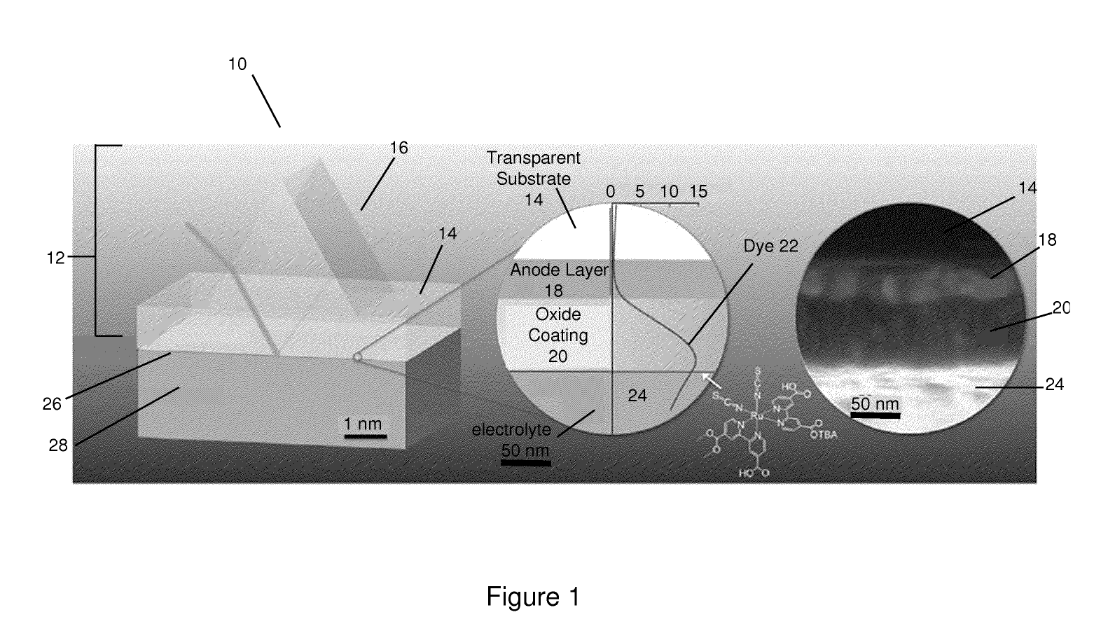

FIG. 1 illustrates one example of a DSSC 10. As illustrated in FIG. 1, the DSSC 10 comprises a photoelectrode 12, at least one spacer 26, and a cathode 28. The photoelectrode 12 comprises a transparent substrate 14, an anode layer 18, an oxide layer 20, and a dye 22. As illustrated in the embodiment of FIG. 1, the transparent substrate 14 is generally planar and includes a prism 16 disposed on a surface of the transparent substrate 14. In one embodiment, the prism 16 is operatively connected to the transparent substrate 14 with an index-matching fluid. However, other alternative embodiments may comprise a transparent substrate 14 with an integral prism 16. Still other alternative embodiments may includes a grating instead of a prism 16. The photoelectrode 12 is fabricated by depositing the anode layer 18 on the transparent substrate 14 (e.g. glass, plastic, or the like) and depositing the oxide layer 20 on the anode layer 18. In the embodiment illustrated in FIG. 1, the anode layer 18 comprises an ultra smooth (e.g. RMS roughness of approximately 1 nm or less) silver film several tens of nanometers in thickness. As illustrated, the anode layer 18 is approximately 40 nanometers, though it could be about 10-100 nanometers for other wavelengths, dyes, and anode layer materials. Similarly, while the anode layer 18 illustrated in FIG. 1 comprises silver, one skilled in the art will recognize that other materials may be used for the anode layer 18. For example, other conductive materials having minimal absorption, such as gold, may be used. In embodiments of the present invention, the dye layer 22 is part of the full optical stack (that includes the metal anode, for example, silver) that absorbs the energy. That the conductive layer/anode layer 18 in the present disclosure is an optically dense film such as silver is a distinguishing aspect of the present disclosure. Traditionally, DSSCs employ a transparent conductive oxide (TCO) layer and semiconducting oxide layer, where the TCO layer transmits light to the semiconducting oxide layer. The DSSC disclosed herein, however, replaces the TCO with a conductive layer such as silver, which conducts light energy to the semiconducting oxide layer.

The oxide layer 20 is deposited on a surface of the anode layer 18. The oxide layer 20 comprises a metal oxide wide-bandgap semiconducting thin film of sub-micron thickness. While the oxide layer 20 illustrated in FIG. 1 comprises ZnO, one skilled in the art will recognize that other metal oxide wide-bandgap semiconducting films with gaps greater than or equal to 2.8 eV may be used. The photoelectrode 12 is then sensitized with a monolayer of dye 22 by depositing the dye 22 on a surface of the oxide layer 20. As illustrated in FIG. 1, the dye 22 is chemically bound to a surface of the oxide layer 20. In other embodiments, the dye 22 may be disposed between the oxide layer 20 and the cathode 28.

With the photoelectrode 12 fabricated, the at least one spacer 26 is disposed between the photoelectrode 12 and the cathode 28, creating a gap, which is filled with an electrolyte 24 as illustrated in FIG. 1. The electrolyte 24 may comprise a solvent, a redox shuttle, and other additives configured to shuttle the holes to the cathode. While the embodiment illustrated in FIG. 1 includes a non-solid electrolyte 24, other hole-transport layers including solid polymers or small-molecule films may also be used. The periphery of the gap created by the at least one spacer 26 is sealed so that the electrolyte 24 does not leak. In this embodiment, light is resonantly coupled across the optically dense silver film, which also serves as a highly conductive anode 18 (Rₛ=1 Ω/square). Thus, as explained above, whereas previous DSSCs require a TCO anode to transmit light into the DSSC, the embodiment illustrated in FIG. 1 implements an optically dense anode 18 and oxide layer 20 to conduct incident light energy into the DSSC 10.

At normal (e.g. perpendicular) incidence, the photoelectrode 12 exhibits more than 90% reflectivity, however, upon prism coupling in the Kretschmann configuration (see FIG. 1), light can be efficiently coupled into the surface plasmon and higher order guided modes supported by the structure. In coupling to guided modes, dye 22 absorption is maximized through a resonant increase of the electromagnetic field intensity in the plane of the surface-bound dye 22. Put differently, incident light is effectively ‘turned’ to propagate parallel to the oxide layer 20/dye 22 interface, enabling dye absorption over the entire propagation length (>10 um) of the mode. While prism coupling has been used in the context of DSSCs 10 to study dye 22 absorption kinetics and to investigate photocurrent enhancement in nanoparticle-based cells, there have been no reports of photovoltaic performance or any describing enhancement in planar, prism-coupled DSSCs 10. This is likely due to issues related to depositing an oxide layer on a metal film. To be effective, the metal oxide must be pinhole free (to prevent electrical shorting and metal corrosion when electrolyte sees the metal film). The metal oxide also needs to be carefully fired (to allow good dye injection) without damaging the underlying Ag film. All of this was done with atomic layer deposition and careful process optimization. Previous reports used Au (which is worse for cavity modes but easier to process) and did not report PV performance.

The surface plasmon polariton and higher order transverse magnetic (TM) and transverse electric (TE) guided modes are accessible by tuning the thickness of each layer in the stack. The complex refractive indices of each layer were experimentally determined for glass, Ag, ZnO, TiO₂, N719, and the conventional I⁻/I₃⁻ acetonitrile-based electrolyte 24. A standard transfer matrix approach modeled the optical fields in the multilayer structure and the adjacent electrolyte 24. Initially, a genetic algorithm was employed to identify optimal layer thickness combinations that maximize the energy absorbed by the dye 22 monolayer. The largest couplings occur for TE modes in photoelectrodes 12 consisting of Ag and ZnO. This is because the TE boundary conditions and the smaller real component of the ZnO refractive index (n=2.0), as compared to that of TiO₂ (n =2.4), lead to smaller modal overlap with the Ag anode 18 and hence less parasitic absorption. Little difference in dye 22 absorption is predicted among the various TE modes. Therefore, experiments focused on the lowest order (TE₀) mode since it minimizes both the layer resistance and any potential loss due to residual color in the ZnO.

The oxide layer 20 used to protect the underlying Ag film were grown by atomic layer deposition (ALD) and characterized using variable-angle spectroscopic ellipsometry (VASE). As a “soft” and layer-by-layer deposition technique, ALD is used to deposit high quality, pinhole free materials with sub-nanometer thickness control without damaging the underlying Ag film. The large number of metal oxides accessible by ALD (including, but not limited to, TiO₂, ZnO, SnO₂, ZrO₂, and NiO) makes the technique further applicable for the development of future photoelectrochemical systems. Detailed properties of the resulting polycrystalline films, including complex indices of refraction and film thickness are determined through VASE and transmission measurements, and serve as inputs for the transfer matrix modeling.

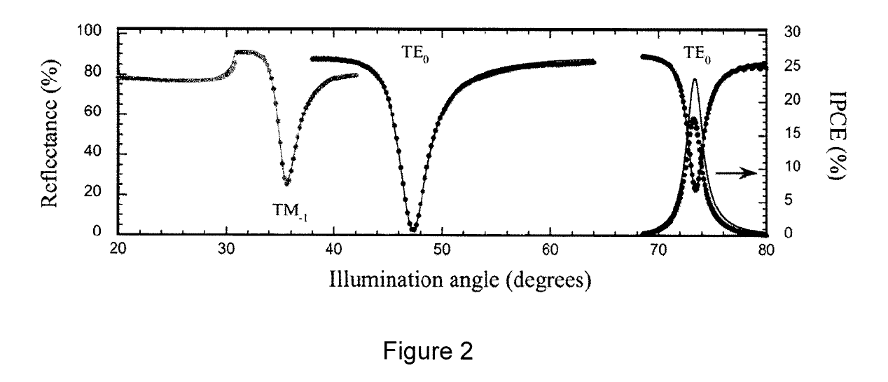

As shown in FIG. 2, the quality of the structures are assessed at each stage of fabrication by measuring reflectivity (solid circles) at λ=543 nm and comparing it with that predicted by the model (lines). There is excellent agreement progressing from the surface plasmon mode of the bare Ag film (37°) to the TE₀ mode of the photoelectrode 12 in air (47°) and in electrolyte 24 (74°). The reflectivity dip of the photoelectrode 12 in air prior to device completion approaches zero, implying 100% coupling into the structure on resonance. Immersed in electrolyte 24, the reflectance of the device increases to 21% and the resonance shifts to higher angle due to the increase in effective index of the mode. On resonance, an IPCE of 17.4% is achieved, which is lower than the LHE of 24% predicted by the model. The difference may reflect a non-unity absorbed photon to current efficiency (APCE) but more likely results from the difficulty in accurately characterizing the thickness and optical constants for a monolayer of adsorbed dye 22 which, from a modeling standpoint, probably reflects an effective medium approximation since the semiconductor surface roughness exceeds the size of dye 22 molecule.

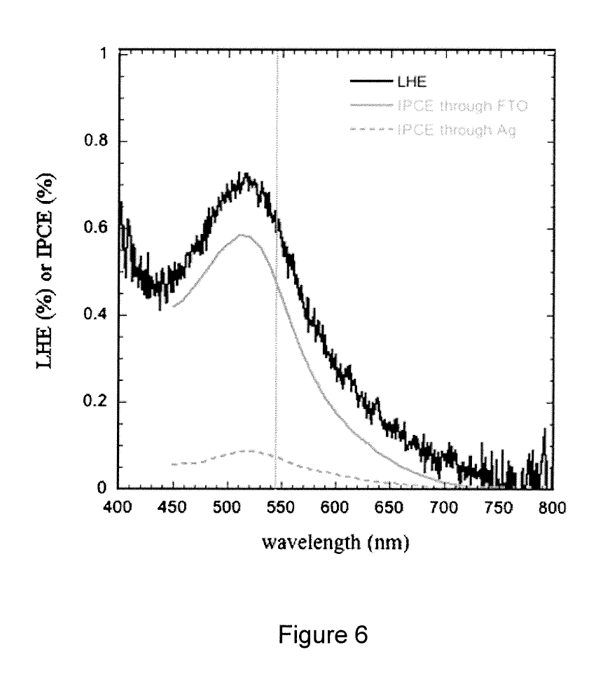

According to the model, the balance of non-reflected power (79%) that is not absorbed by the dye 22 (55%) is lost to parasitic absorption by the adjacent Ag anode 18, which competes effectively as a power dissipation channel due to the low optical density of the dye 22. Nevertheless, the advantage of resonant coupling is significant, representing a 35-fold enhancement over the IPCE=0.5% measured (0.6% predicted, FIG. 6) at normal incidence (λ=540 nm) for a control device on a TCO substrate. This enhancement is several times greater than those observed when applying similar strategies to organic and inorganic photovoltaics owing to a higher modal quality factor that results from the combination of low intrinsic absorbance by the dye 22 monolayer and field penetration into the electrolyte 24 which minimizes dissipation in the Ag.

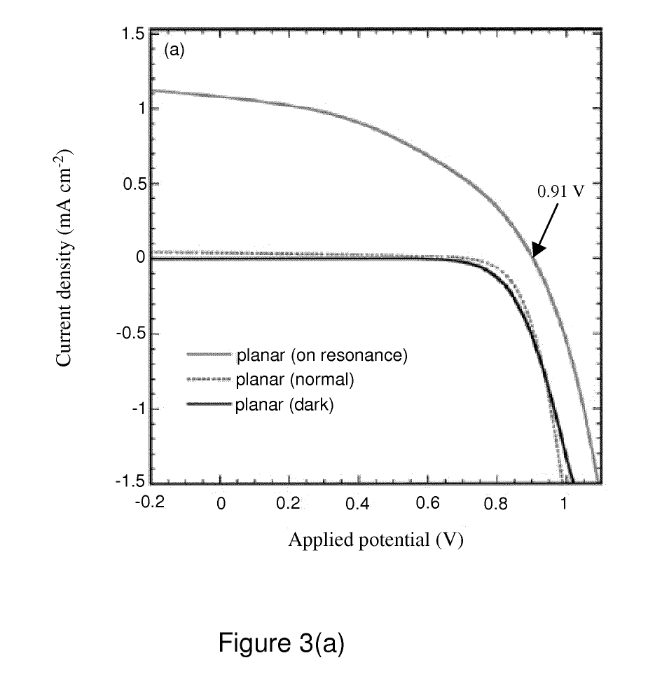

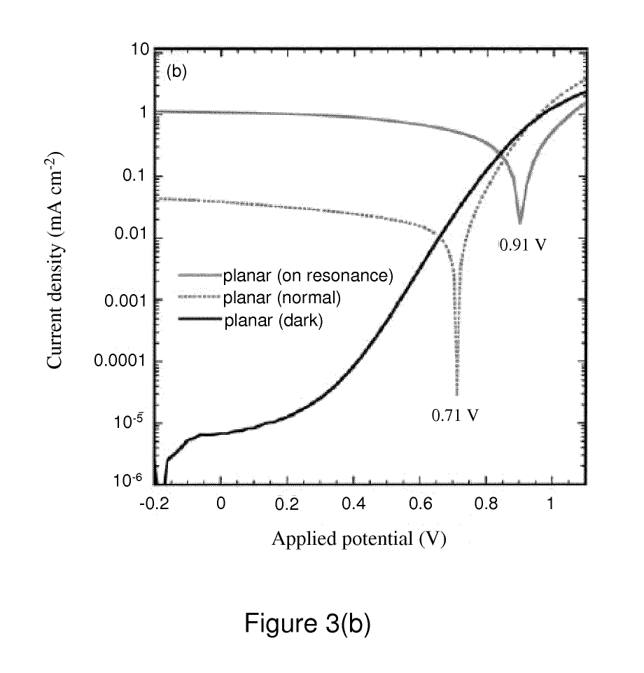

As illustrated in FIGS. 3(a)-(b), the dark current of the present invention is exceptionally low. As the following equation indicates, dark currents were fit according to the diode equation and include a small capacitive offset current to account for the non-origin crossing that is treated equivalently to a photocurrent in the dark:

$$J = {Offset}_{cap} - {J}_{sat} ( {e}^{q ( V + {JAR}_{s} ) / mkT} - 1 ) + \frac{V + {JAR}_{s}}{{R}_{sh}} .$$

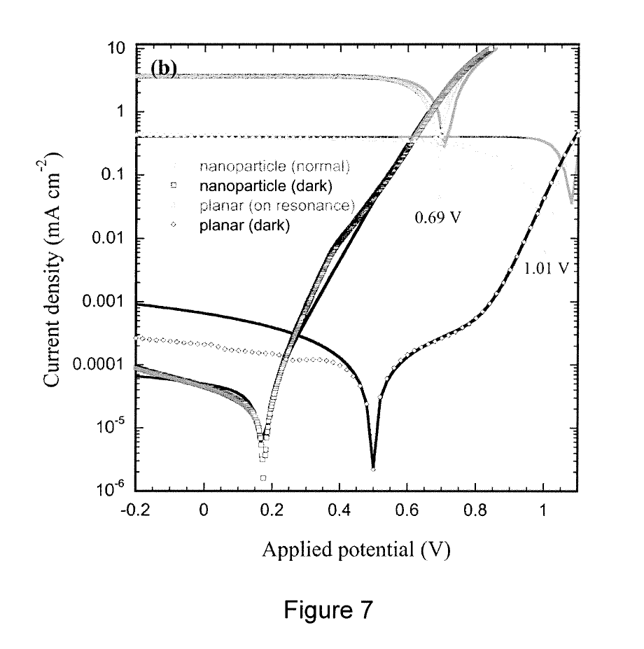

The dark parameters were held constant when fitting the photocurrent, only the photogenerated current, Jₚₕₒₜₒ was fit. Table 1 summarizes the fit parameters used in the fits plotted in FIG. 7.

TABLE 1

| | | | | m | | |
|---|---|---|---|---|---|---|
| | Jₛₐₜ | Rₛₕᵤₙₜ | Rₛₑᵣᵢₑₛ | (ideality) | Offset_{cap} | Jₚₕₒₜₒ |
| Units | mA cm⁻² | kOhm cm² | kOhm | unitless | mA cm⁻² | mA |
| | | | | | | cm⁻² |
| Nano- | 9E−7 | 13000 | 0.009 | 1.81 | 5E−5 | 3.6 |
| particle | | | | | | |
| Planar | 11.7E−14 | 760 | 0.036 | 1.35 | 6.5E−4 | 0.4 |

With reference to FIGS. 3(a)-(b), upon monochromatic illumination at λ=543 nm with incident intensity I_{inc}=18.3 mW cm⁻², representing a photon flux (4.8×10¹⁶ s⁻¹ cm⁻²) lower than the AM1.5 photon flux integrated only to the illumination wavelength (6.6×10¹⁶ s⁻¹ cm⁻²), the V_{oc} of the ZnO-based devices routinely exceeds 900 mV, which surpasses that of any other ZnO-based DSSC 10 reported to date. Flat photoelectrodes 12, with near unity roughness, project a specific surface area at least 1000-fold less than that of conventional nanoparticle photoelectrodes 12. As the dark current roughly scales with surface area, a proportional decrease in the dark reaction should occur. The high V_{oc} measured here is attributed to a dark current density that is several 1000-fold less than that of ZnO nanoparticle-based devices.

Photocurrent densities at short circuit (J_{sc}) of 1.1 mA cm⁻² were measured on resonance and would extrapolate to 3.6 mA/cm² under an AM1.5-equivalent photon flux (again, integrated out to the optical bandgap of the dye 22). A fill factor (FF) of 0.42 results in a monochromatic power efficiency of 2.3% under TE-polarized illumination at the peak resonant condition.

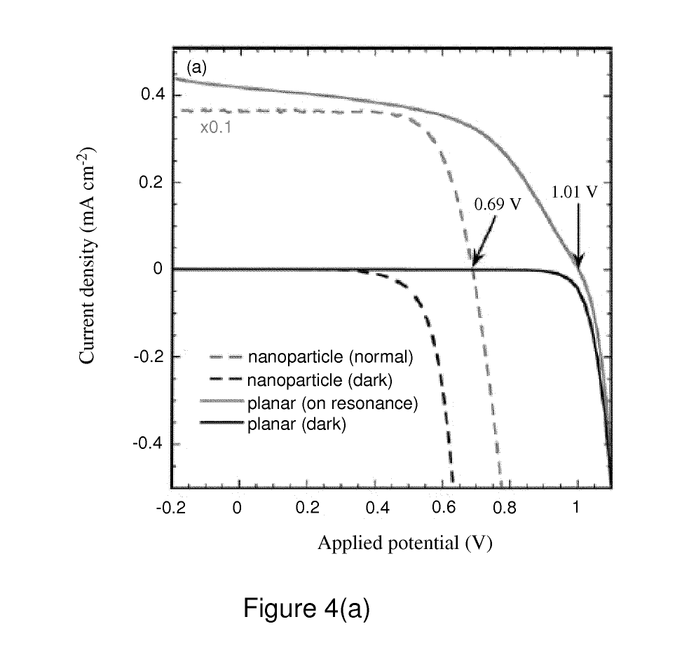

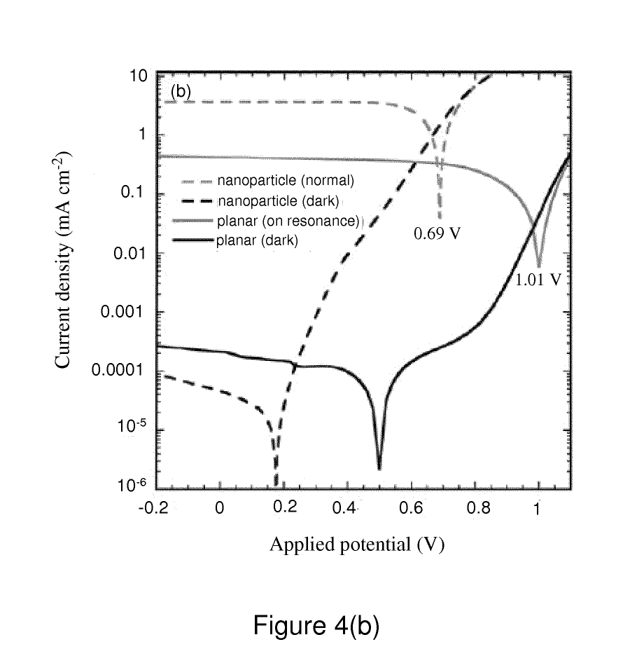

Although the model suggests that the lower index of ZnO is suited to maximize optical coupling to the dye 22, TiO₂ is the preferred material for efficient DSSCs 10. Nanoparticle ZnO and TiO₂ devices both show J_{SC} as approximately 18 mA cm⁻² but the FF and V_{oc} are consistently higher in TiO₂ heterojunctions relative to their ZnO equivalent. Both pure TiO₂ and ZnO/TiO₂ bilayers were considered for use in cavity-mode-enhanced DSSCs 10. ZnO/TiO₂ bilayer films were pursued, however, because (1) TiO₂ exhibits a propensity for pinholes, and (2) the dye 22 optical coupling predicted for pure TiO₂ devices is less than 15% due to strong modal confinement and field penetration of the Ag anode 18 that result from the high TiO₂ refractive index. Ideally, a TiO₂ shell would allow for increased FF and V_{oc} while only marginally reducing the predicted maximum dye 22 coupling to 18%. FIGS. 4(a)-(b) show that upon substituting a 20 nm thick TiO₂ shell for the outermost 30 nm of ZnO, the IPCE peaks at 8% on resonance. This is lower than the equivalent ZnO-based device (see FIGS. 3(a)-(b)), yet leads to a substantial increase in V_{oc} up to 1.01 V. This is the first report of a DSSC 10 to reach this landmark with the standard (I⁻/I₃⁻) redox couple. Again, the high V_{oc} measured here is attributed to a dark current density that is several 1000-fold less than that of traditional nanoparticle-based devices. Fitting the dark current-voltage characteristic to the diode equation (FIG. 7) confirms that the dark saturation current is many orders of magnitude lower than that of an analogous nanoparticle-based device.

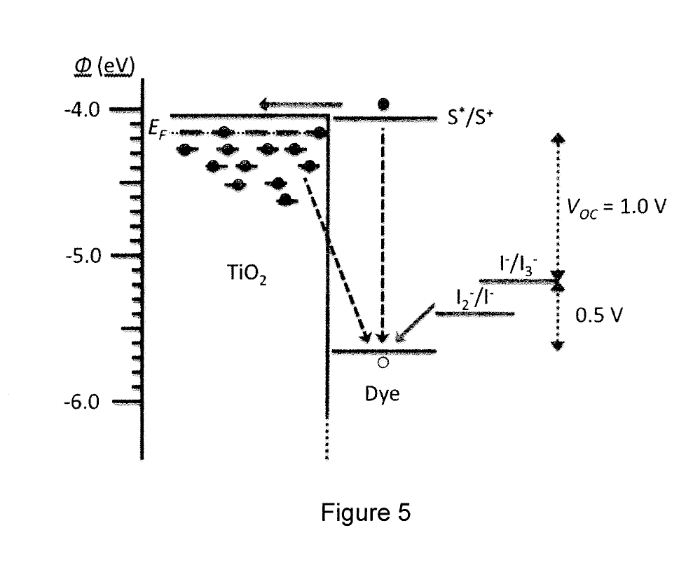

The J-V curve under resonant illumination in FIG. 4(a) displays an atypical ‘kink’ for V>0.8 V, which does not result from series resistance because it is not evident in the dark current. The effect is most evident upon comparing the dark and illuminated current densities at an applied bias of 900 mV. Here, the total current under illumination, which represents the superposition of dark and photogenerated currents, is significantly reduced despite an insignificant contribution from the dark current. The consequent reduction in photogenerated current is rationalized according to the energy level diagram in FIG. 5. Given the fixed potential of the cathode in contact with the electrolyte 24, large applied potentials drive up the quasi-Fermi level in the TiO₂. At 1.0 V, only a limited amount of driving force (0.1 V) remains for electron injection from the dye 22 excited state. Accordingly, injection efficiencies have been observed to drop sharply at large applied potentials. Rapid electron recombination with the oxidized dye 22 (parasitic pathway), which is in competition with reduction by I⁻ (the preferred pathway) has also been observed at large applied potentials. The signature of one or both effects is the loss of photogenerated current at high applied potential independent of dark current. That the loss of electron injection efficiency or charge separation efficiency (or both) is dominant at large applied potentials is supported by FIG. 4(a) . The data thus suggest that in the limit of greater LHE and lower dark current, the V_{oc} is unlikely to ever significantly exceed 1.0 V in this particular system, as illustrated in FIG. 5. Combined with previously observed low photogenerated electron yields at high applied potentials, the data implies that this configuration has approached the fundamental limit in photovoltage feasible for the most popular DSSC 10 (I⁻/I₃⁻+N719) configuration.

Although the strategy described herein exhibits several practical shortcomings, most prominently that the IPCE enhancement occurs over a small angle of incidence for each monochromatic illumination wavelength and applies to only half of an unpolarized light source, the benefits of a flat dye-sensitized photoelectrode 12 are revealing. For example, there is an important kinetic competition between the electron survival time and the relatively long electron transport time through the nanoporous framework that determines charge collection efficiency. In the limit of these thin film photoelectrodes 12, the orders of magnitude shorter transport time renders this competition void. Similarly, the choice of redox shuttle is typically limited to highly soluble species whose high concentration sufficiently lowers the mass transport resistance to “hole” transport across the 25 micron electrode separation. By using a flat photoelectrode 12 this span may be decreased to approximately 500 nm, at which point the guided mode fields would begin to overlap with and leak into the platinized cathode. In the case of such a small electrode gap, the need for preformed oxidized species in solution is minimized. As the dark current roughly scales with the oxidized species concentration, this will pay dividends on well-known redox solutions and creates the opportunity to employ new couples. Therefore, these results are expected to dramatically expand the multivariable space over which DSSCs 10 can be explored.

While conventional DSSC 10 components (dyes 22, redox shuttles, spacers 26) have been used for the purpose of comparison, the design may benefit significantly from improved chemistries already demonstrated for use in DSSCs 10. For example, using high extinction dyes 22 such as, e.g. squaraines at their absorbance peak, may achieve an on-resonance LHE>62% due to more favorable competition with parasitic power dissipation in the Ag anode 18. Any practical application of this approach will, of course, require a route to broadband, polarization-independent enhancement at normal incidence, similar to solar radiation. Antennae-based approaches provide one potential solution, in which light is absorbed by an adjacent, optically thick absorber layer and then predominantly re-emitted into the waveguide modes of the planar DSSC 10 analogous to that demonstrated here. Alternatively, in-plane structural periodicity or the use of metal nanoparticles could be used to efficiently scatter incident light into waveguide modes. More generally, the wealth of knowledge developed in the context of traditional thin-film solar cell light management is applicable to the architecture studied here, raising the prospect for efficient DSSCs 10 with modest roughness and the benefits revealed herein. These results supply new insight into processes presently limiting DSSCs 10 and point to novel strategies to overcome these losses.

While the forgoing description has described improving the efficiency of converting solar energy into electric energy, another alternate embodiment is directed to converting solar energy into a fuel. In this embodiment, by exposing the photoelectrode 12 (with or without a dye 22) to catalysts, solar energy is directly converted into a fuel. This process is described in detail in Michael G. Walter et al., Solar Water Splitting Cells, Chem. Rev., 2010, 110, 6446-6473, and Roel van de Krol et al., Solar Hydrogen Production with Nanostructured Metal Oxides, J. Mater. Chem., 2008, 18, 2311-2320, which are hereby fully incorporated by reference.

### EXAMPLES

A DSSC employing this improved light harvesting approach was made by first solvent-cleaning corning 1737 display grade glass and blow-drying the glass with a particle-filtered N₂ stream. A thin (2.0 nm) Ge film was evaporated from a W boat under 5×10⁻⁷ Torr vacuum at a rate of 0.01 nm/s. The Ge film serves as an adhesion layer for and reduces the roughness of the subsequent Ag film (38 nm, 0.05 nm/s) deposited from a Mo boat without breaking vacuum as more fully described in Vj, L.; Kobayashi, N. P.; Islam, M. S.; Wu, W.; Chaturvedi, P.; Fang, N. X.; Wang, S. Y.; Williams, R. S. Nano Lett. 2009, 9, 178, incorporated herein by reference. The films are annealed overnight under flowing Ar at 450° C. (2° C. deg/min ramp rates, 30 min soak).

After fully cooling, the samples are promptly transferred to the 60° C. sample stage of an ALD tool (Savannah 200, Cambridge Nanotech). Metal oxides (Al₂O₃, ZnO or TiO₂) were deposited by dosing trimethyl aluminum (TMA), diethyl zinc (DEZ), or titanium isopropoxide (TTIP), respectively, alternately with water. The (metal precursor)-(N₂ purge)-(H₂O)-(N₂ purge) timings were x-60-0.015-60 where x=0.015 s for DEZ and TMA or 0.15 s for TTIP. Two cycles of Al₂O₃ were first deposited to improve adhesion and promote oxide nucleation.

Subsequently, 4 nm of ZnO was deposited to further protect the Ag film before ramping the temperature up to 140° C. for ZnO and finally 225° C. for TiO₂. The remainder of each film thickness was deposited at these higher temperatures with purge times reduced to 20 s for ZnO or 7 s for TiO₂. After cooling back to 80° C. the samples were removed, transferred to a quartz tube furnace and annealed overnight under flowing O₂ at 400° C. (2° C. deg/min ramp rates, 10 min soak). Both the Ag and metal oxide film quality and thickness were monitored by ex-situ variable angle spectroscopic ellipsometry (VASE) throughout the fabrication procedure. It should be noted that the entire photoelectrode fabrication is a careful balance between preserving the ultra-smooth Ag film and sufficiently oxidizing the overlying metal oxide for efficient DSSC operation. Once optimized, batch yields greater than 80% were found to be of device quality pinhole free.

Finally, each sample was soaked in an ethanoic solution of 0.5 mM (Bu₄N)₂[Ru(4-(COOH),4′-(COO)-2,2′-bipyridine)₂(NCS)₂] (“N719”, Dyesol, B2 dye) for 30 min (ZnO) or 2.5 hours (bilayer ZnO/TiO₂) and rinsed with dry acetonitrile before the devices were assembled according to established methods as more fully set forth in Nazeeruddin, M. K.; De Angelis, F.; Fantacci, S.; Selloni, A.; Viscardi, G.; Liska, P.; Ito, S.; Bessho, T.; Gratzel, M. J. Am. Chem. Soc. 2005, 127, 16835, incorporated herein by reference. Briefly, a 25 μm Surlyn spacer (Solaronix SX1170-25) was sandwiched between the photoelectrode and a platinized fluorine doped tin oxide (FTO) dark electrode. A 0.07 cm² active area was defined by a spacer, which softens at 80° C. to seal the device. Planar control devices without cavity mode enhancement were constructed on FTO without Ge or Ag layers. Nanoparticle control devices were constructed on FTO by doctor-blading a transparent and opaque nanoparticle paste and firing to 500° C. under flowing O₂. The total nanoparticle film thickness was ˜8 um.

A solution of 0.6 M butylmethylimidizolium iodide (TCI America), 0.1 M lithium iodide, 0.03 M I₂, and 0.25 M tert-butylpyridine in acetonitrile was introduced into the cell via vacuum backfilling through a hole in the platinized FTO electrode. A second Surlyn spacer and microscope coverslip were sealed over the hole with a soldering iron. All chemicals were used as received from Sigma-Aldrich unless otherwise specified.

Normal incidence illumination for spectral response experiments was achieved with an IPCE measurement kit (Newport) that consists of an excitation monochromator coupled to a 300W Xe lamp with AM1.5 filter and calibrated with a Si photodiode. IPCE and broadband (Iᵢₙₜ=83 mW/cm²) normal incidence J-V data were measured with a potentiostat (Metrohm, Autolab III) in a two-electrode configuration. Reflectivity measurements were conducted by prism-coupling the 543 nm line of a HeNe laser into the device, which was mounted on a computer controlled rotation stage, with a Si photodiode and lock-in amplifier used for detection.

The LHE of dyed photoelectrodes was derived from the subtraction of absorption spectra acquired before and after dye removal (with 0.1 M KOH in H₂O) on a UV-Vis-NIR spectrophotometer (Varian Cary 5000). As illustrated in FIG. 7, the LHE of N719 dye on planar photoanodes is less than 1%. When light is normally incident upon control devices with TCO anode (no Ag) IPCEs are similar to the LHE. The Ag anode in cavity mode enhanced DSSC acts as a broadband neutral density filter resulting in lower IPCEs under normal incidence. The shape of each spectrum is characteristic of the N719 dye.

The foregoing description of embodiments of the present invention have been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments, and with various modifications, as are suited to the particular use contemplated.

What is claimed is:

1. A dye-sensitized solar cell comprising:
a transparent substrate;
an anode layer deposited on the transparent substrate;
an oxide layer deposited on the anode layer;
a dye layer deposited on the oxide layer;
a cathode disposed adjacent to the dye layer; and
an electrolyte disposed between the anode layer and the cathode.

2. The dye-sensitized solar cell of claim 1, wherein the transparent substrate is planar.

3. The dye-sensitized solar cell of claim 1, wherein the transparent substrate further comprises a prism.

4. The dye-sensitized solar cell of claim 1, further comprising an at least one spacer disposed between the anode layer and the cathode, the at least one spacer forming a gap between the anode layer and the cathode.

5. The dye-sensitized solar cell of claim 4, wherein the gap formed by the at least one spacer is sealed such that the electrolyte does not leak.

6. The dye-sensitized solar cell of claim 1, wherein the transparent substrate is resonantly coupled across the anode layer.

7. The dye-sensitized solar cell of claim 3, wherein the transparent substrate is prism-coupled across the anode layer such that a light incident to a surface of the dye-sensitized solar cell propagates parallel to an interface between the anode layer and the cathode.

8. The dye-sensitized solar cell of claim 1, wherein the anode layer is silver.

9. The dye-sensitized solar cell of claim 1, wherein the anode layer is configured to be about 10 to about 100 nanometers thick.

10. The dye-sensitized solar cell of claim 1, wherein the oxide layer comprises a wide-bandgap oxide film having a thickness of one micron or less.

11. The dye-sensitized solar cell of claim 1, wherein the oxide layer is deposited onto the anode layer by atomic layer deposition.

12. The dye-sensitized solar cell of claim 1, wherein the dye layer is ruthenium-based.

13. The dye-sensitized solar cell of claim 1, wherein the electrolyte is iodide-based.

14. A method of improving the efficiency of a dye-sensitized solar cell, comprising:
providing a planar transparent substrate;
depositing an anode layer on a surface of the planar transparent substrate;
depositing an oxide layer on a surface of the anode layer;
depositing a dye layer on a surface of the oxide layer;
operatively connecting a cathode to the planar transparent substrate such that a gap is formed between the planar transparent substrate and the cathode; and
depositing an electrolyte within the gap,
wherein a light incident on the planar transparent substrate is resonantly coupled across the anode layer.

15. The method of claim 14, further comprising sealing a periphery of the gap formed between the planar transparent substrate and the cathode such that the electrolyte does not leak.

16. The method of claim 14, wherein the planar transparent substrate is prism-coupled to the cathode such that a light incident to a surface of the dye-sensitized solar cell propagates parallel to an interface between the anode layer and the cathode.

17. The method of claim 14, wherein the anode layer is silver.

18. The method of claim 14, wherein the anode layer is configured to be about 10 to about 100 nanometers thick.

19. The method of claim 14, wherein the oxide layer comprises a wide-bandgap oxide film having a thickness of one micron or less.

20. The method of claim 14, wherein the oxide layer is deposited onto the anode layer by atomic layer deposition.
